(19) United States
(12) Patent Application Publication
(10) Pub. No.: US 2009/0215277 A1
(43) Pub. Date: Aug. 27, 2009

(54) DUAL CONTACT ETCH STOP LAYER PROCESS

(76) Inventors: Tung-Hsing Lee, Taipei County (TW); Ming-Tzong Yang, Hsinchu County (TW); Ching-Chung Ko, Hsinchu County (TW); Tien-Chang Chang, Hsinchu City (TW); Yu-Tung Chang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/037,089

(22) Filed: Feb. 26, 2008

(51) Int. Cl. H01L 21/31

(52) U.S. Cl. 438/761; 257/E21.209

(57) ABSTRACT

A dual CESL process includes: (1) providing a substrate having thereon a first device region, a second device region and a shallow trench isolation (STI) region between the first and second device regions; (2) forming a first-stress imparting film with a first stress over the substrate, wherein the first-stress imparting film does not cover the second device region; and (3) forming a second-stress imparting film with a second stress over the substrate, wherein the second-stress imparting film does not cover the first device region, an overlapped boundary between the first- and second-stress imparting films is created directly above the STI region, and wherein the overlapped boundary is placed in close proximity to the second device region in order to induce the first stress to a channel region thereof in a transversal direction.

### BACKGROUND OF THE INVENTION

1. Field of the Invention

The invention relates generally to a method for fabricating semiconductor devices. More particularly, the invention relates to an improved dual contact etch stop layer (dual CESL) technique for straining both the NMOS and PMOS transistor channels.

2. Description of the Prior Art

For decades, chip manufacturers have made metal-oxide-semiconductor (MOS) transistors faster by making them smaller. As the semiconductor processes advance to very deep sub micron era such as 65-nm node or beyond that to 45 nm, how to increase the driving current for MOS transistors has become a critical issue.

In order to improve device performance, crystal strain technology has been developed. Crystal strain technology is becoming more and more attractive as a means for getting better performance in the field of CMOS transistor fabrication. Putting a strain on a semiconductor crystal alters the speed at which charges move through that crystal. Strain makes CMOS transistors work better by enabling electrical charges, such as electrons, to pass more easily through the silicon lattice of the gate channel.

Generally, strain in silicon can be induced in different ways: through stresses created by films in a form of poly stressor or contact etch stop layer (CESL) and structures that surround the transistor, called process-induced strain, or by employing a strained silicon wafer, where the top layer of silicon has typically been grown on top of a crystalline lattice that is larger than that of silicon. Most leading-edge chip manufacturers employ process-induced stress in some form in production today, typically tensile nitrides to improve NMOS device performance. As known in the art, tensile stress improves electron mobility and compressive stress improves hole mobility.

A dual CESL approach appears to be the leading candidate for inducing stress in scaled CMOS devices. According to this approach, after transistor formation, a tensile nitride layer is laid down, masked, and etched off the PMOS regions. A compressive nitride layer is then put down, masked, and etched off the NMOS areas. It is known that NMOS transistors prefer a combination of tensile stress in the parallel direction along the channel and compressive stress in the vertical direction perpendicular to the wafer surface. In contrast, PMOS transistors prefer compressive stress in the parallel direction (parallel to current flow). While tensile stress in the in-plane direction perpendicular to the direction of the current is theoretically beneficial for both NMOS and PMOS transistors, that effect is difficult to obtain using conventional local-strain technique.

There is always a need in this industry to provide an applicable method that can result in better transistor performance.

### SUMMARY OF THE INVENTION

It is one object of this invention to provide an improved dual CESL process in order to enhance device performance.

According to the claimed invention, a dual CESL process includes the steps of (1) providing a substrate having thereon a first device region, a second device region and a shallow trench isolation (STI) region between the first and second device regions; (2) forming a first-stress imparting film with a first stress over the substrate, wherein the first-stress imparting film does not cover the second device region; and (3) forming a second-stress imparting film with a second stress over the substrate, wherein the second-stress imparting film does not cover the first device region, an overlapped boundary between the first- and second-stress imparting films is created directly above the STI region, and wherein the overlapped boundary is placed in close proximity to the second device region in order to induce the first stress to a channel region thereof in a transversal direction.

From another aspect, the dual CESL process of this invention includes: (1) providing a substrate having thereon a first device region, a second device region and a shallow trench isolation (STI) region between the first and second device regions, wherein a gate structure overlies the first device region, the second device region and the STI region, and wherein the gate structure comprises a contact region on the STI region, which is approximately at the middle point between the first and second device regions; (2) forming a first-stress imparting film with a first stress over the substrate, wherein the first-stress imparting film does not cover the second device region; and (3) forming a second-stress imparting film with a second stress over the substrate, wherein the second-stress imparting film does not cover the first device region, an overlapped boundary between the first- and second-stress imparting films is created directly above the STI region, and wherein the overlapped boundary is placed in close proximity to the second device region and does not overlap with the contact region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-7 are schematic diagrams showing the preferred embodiment of the present invention method, wherein FIGS. 1 and 7 are planar views showing the transistor pair, and FIGS. 2-6 include cross sectional views taken along lines I-I′, II-II′ and III-III′ of FIG. 1.

### DETAILED DESCRIPTION

The present invention pertains to an improved dual CESL process that utilizing a tensile CESL and a compressive CESL for straining the NMOS and PMOS transistor channels, respectively. The present invention can be employed primarily for boosting the PMOS performance. From one aspect, the present invention provides a new rule for the dual CESL process without increasing the process complexity and cost.

For the sake of clarity, the following directional terms: channel length direction, parallel direction, source-to-drain direction, current flow direction are collectively referred to herein as “longitudinal direction”, while the following directional terms: channel width direction, in-plane direction perpendicular to the direction of the current, in-plane direction perpendicular to the source-to-drain direction, and in-plane direction perpendicular to the channel length direction are collectively referred to as “transversal direction”.

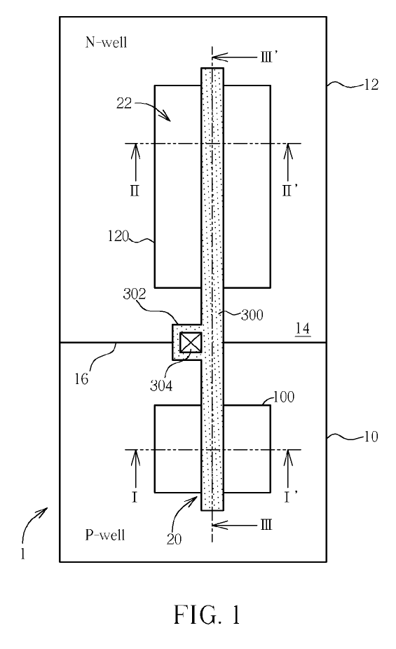

The preferred embodiment of the present invention method is now described in detail with reference to FIGS. 1-7.

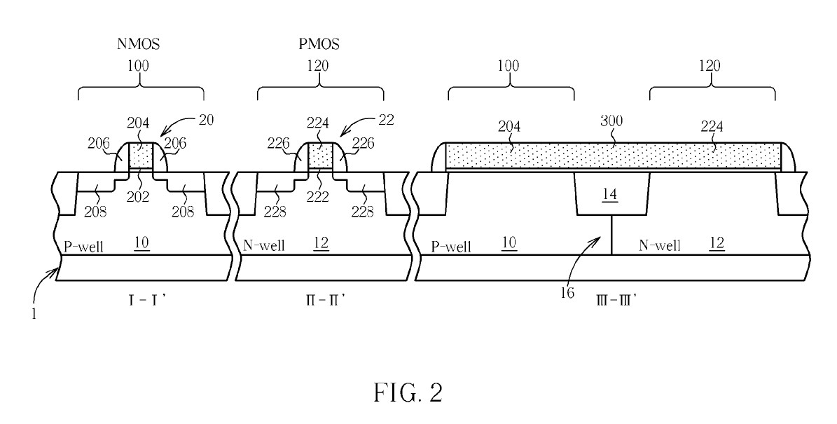

Please refer to FIGS. 1 and 2, wherein FIG. 1 is a planar view showing a portion of the layout of a preferred, exemplary CMOS device according to this invention, and FIG. 2 demonstrates the cross sectional views taken along lines I-I′, II-II′ and III-III′ of FIG. 1, respectively. As shown in FIGS. 1 and 2, a semiconductor substrate 1 is provided. The semiconductor substrate 1 may be a silicon substrate, strained semiconductor, compound semiconductor, silicon-on-insulator (SOI) substrate or any other suitable semiconductor substrates. The semiconductor substrate 1 includes a P well region 10 and an N well region 12. A shallow trench isolation (STI) region 14 is provided in the semiconductor substrate 1 to isolate an active area 100 from an adjacent active area 120.

A well boundary 16 between the P well region 10 and the N well region 12 is situated underneath the STI region 14. Ordinarily, the well boundary 16 is typically at the middle point of the STI region 14 between the active areas 100 and 120. The P well region 10 and N well region 12 may be formed by conventional methods, for example, a masking process followed by ion implantation and activation annealing.

An NMOS device 20 and a PMOS device 22 are formed on the active areas 100 and 120, respectively. The NMOS device 20 and the PMOS device 22 may be formed by conventional methods. The NMOS device 20 and the PMOS device 22 comprise gate structures including gate dielectric layers 202 and 222 and gate electrode portions 204 and 224, respectively. The gate electrode portions 204 and 224 may comprise polysilicon and silicides. The gate dielectric layers 202 and 222 may be formed of silicon oxide, silicon oxy-nitride, silicon nitride, nitrogen doped silicon oxide, high-K dielectrics, or combinations thereof. The high-K dielectrics may include metal oxides, metal silicates, metal nitrides, transition metal-oxides, transition metal silicates, metal aluminates, and transition metal nitrides, or combinations thereof.

The gate dielectric layers 202 and 222 may be formed by any process known in the art, e.g., thermal oxidation, nitridation, sputter deposition, or chemical vapor deposition. The physical thickness of the gate dielectric layers 202 and 222 may be in the range of 5 to 100 Angstroms. The gate electrode portions 204 and 224 may be formed of doped polysilicon, polysilicon-germanium, metals, metal silicides, metal nitrides, or conductive metal oxides. In a preferred embodiment, the gate electrodes are formed of doped polysilicon.

Spacers 206 and 226, which may be formed of composite oxide/nitride materials, are formed along either side of the NMOS and PMOS gate sidewalls by depositing one or more layers of silicon oxide, silicon nitride and/or silicon oxy-nitride, followed by wet or dry etching away portions of the one or more layers. It will be appreciated that the spacers may include first forming an offset liner (not shown), e.g., oxide adjacent the gate structure to space a subsequently formed LDD doped region away from the gate structure.

In addition, ion implanted source and drain (S/D) regions 208 and 228 are formed in the substrate, for example following the formation of the spacers 206 and 226. A protective oxide layer (not shown) may be formed over the surface prior to an activation anneal of the S/D regions 208 and 228 and later removed prior to a salicide formation process. Further, self-aligned silicide or salicide (not shown) may be formed over the S/D regions 208 and 228 and over the upper portion of the gate electrodes.

As best seen in FIG. 1, according to the preferred embodiment of this invention, the gate structure of the NMOS device 20 and the gate structure of the PMOS device 22 are electrically connected to each other through a connecting gate portion 300 over the STI region 14 between the active areas 100 and 120. According to the preferred embodiment of this invention, the connecting gate portion 300 further comprises a laterally extending contact region 302, which is approximately at the middle point between the active areas 100 and 120. A contact plug 304 having a dimension of, for example, 60 nm×60 nm, is formed directly on the contact region 302. The well boundary 16 usually passes directly underneath the contact region 302. It is understood that the contact region 302 and the contact plug 304 may be omitted in another embodiment.

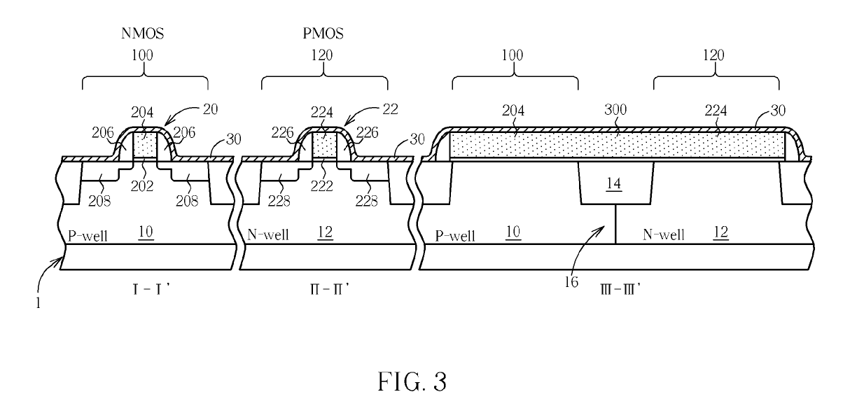

Referring to FIG. 3, a tensile contact etch stop layer (T-CESL) 30, is formed over the NMOS and PMOS device regions to cover respective NMOS and PMOS devices 20 and 22. Preferably, the tensile CESL 30 has tensile stress between about 500 MPa and about 10 GPa, but not limited thereto. The tensile CESL 30 may be formed of silicon oxide, silicon nitride, silicon oxy-nitride, or combinations thereof, but is more preferably formed of silicon nitride by plasma enhanced CVD (PECVD) mixed frequency process.

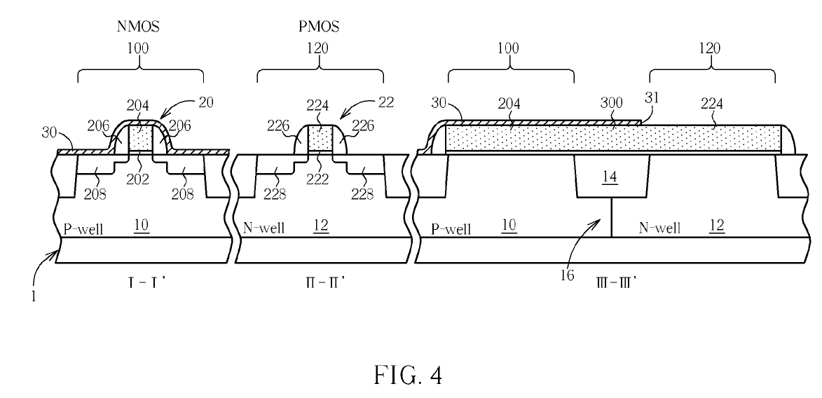

Referring to FIG. 4, the tensile CESL 30 is masked and etched off the PMOS region by conventional methods. For example, a conventional lithographic process is performed to form a patterned photoresist layer (not shown) on the tensile CESL 30. The patterned photoresist layer covers the NMOS region, but reveals the PMOS region. Thereafter, a dry etching process is carried out to etch away the exposed tensile CESL 30 from the PMOS region. After the dry etching process, the remaining photoresist layer is stripped off. It is noteworthy that the front edge 31 of the tensile CESL 30 is in close proximity to the active area 120 and is deliberately not aligned with the well boundary 16. In addition, the front edge 31 of the tensile CESL 30 does not overlap with the contact region 302.

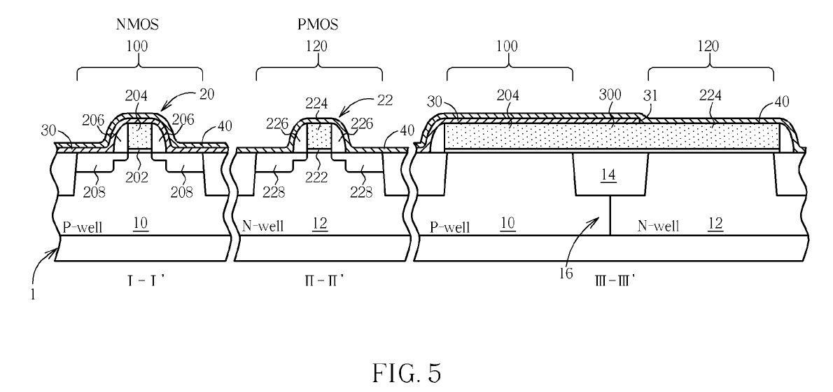

Referring to FIG. 5, a compressive contact etch stop layer (C-CESL) 40, is formed over the NMOS and PMOS device regions. The compressive CESL 40 overlies the tensile CESL 30. The compressive CESL 40 may be formed of silicon oxide, silicon nitride, silicon oxy-nitride, or combinations thereof, but is more preferably formed of PECVD nitride. Preferably, the compressive CESL 40 has a thickness ranging between 300 angstroms and 800 angstroms, more preferably 400 angstroms and 700 angstroms.

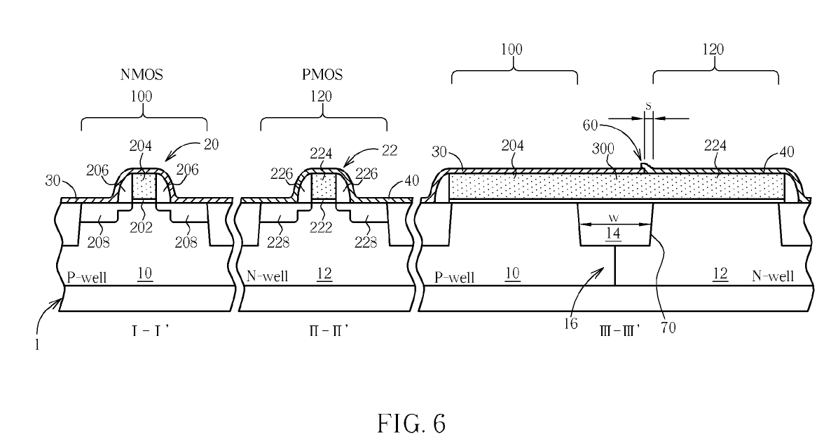

Referring to FIG. 6, likewise, the compressive CESL 40 is masked and etched off the NMOS region by conventional methods. For example, a conventional lithographic process is performed to form a patterned photoresist layer (not shown) on the compressive CESL 40. The patterned photoresist layer covers the PMOS region, but reveals the NMOS region. A dry etching process is then carried out to etch away the exposed compressive CESL 40 from the NMOS region. The remaining photoresist layer is then stripped off. A portion of the compressive CESL 40 extends to the upper surface of the tensile CESL 30 to create an overlapped boundary 60 between the tensile CESL 30 and the compressive CESL 40. Deliberately, the overlapped boundary 60 is not aligned with the well boundary 16.

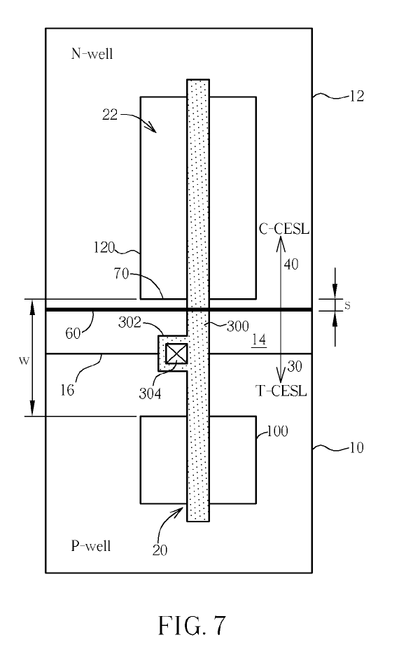

Please refer to FIG. 7 and briefly back to FIG. 6, according to the preferred embodiment of this invention, the overlapped boundary 60 is placed in close proximity to the active area 120 in order to induce tensile stress to the PMOS channel region in the transversal direction. Therefore, the PMOS drive current is enhanced. In another embodiment, the overlapped boundary 60 may be aligned with the boundary 70 between the STI region 14 and the active area 120. Preferably, the spacing s between the overlapped boundary 60 and the boundary 70 is less than or equal to one fourth of the spacing w between the active areas 100 and 120 (s≦¼ w). In addition, as best seen in FIG. 7, since the overlapped boundary 60 is deliberately misaligned with the well boundary 16 and does not overlap with the contact region 302, a potential contact etch problem can be avoided during the formation of the contact hole.

Those skilled in the art will readily observe that numerous modifications and alterations of the device and method may be made while retaining the teachings of the invention.

What is claimed is:

1. A dual contact etch stop layer (dual CESL) process, comprising:
providing a substrate having thereon a first device region, a second device region and a shallow trench isolation (STI) region between the first and second device regions;
forming a first-stress imparting film with a first stress over the substrate, wherein the first-stress imparting film does not cover the second device region; and
forming a second-stress imparting film with a second stress over the substrate, wherein the second-stress imparting film does not cover the first device region, an overlapped boundary between the first- and second-stress imparting films is created directly above the STI region, and wherein the overlapped boundary is placed in close proximity to the second device region in order to induce the first stress to a channel region thereof in a transversal direction.

2. The dual CESL process according to claim 1 wherein a well boundary is situated underneath the STI region, and wherein the overlapped boundary is not aligned with the well boundary.

3. The dual CESL process according to claim 1 wherein a spacing s between the overlapped boundary and the STI-second device region boundary is less than or equal to one fourth of a spacing w between the first and second device regions (s≦¼ w).

4. The dual CESL process according to claim 1 wherein the first device region is an NMOS device region and the second device region is a PMOS device region.

5. The dual CESL process according to claim 1 wherein the first-stress imparting film is a tensile contact etch stop layer (T-CESL).

6. The dual CESL process according to claim 5 wherein the first-stress imparting film is made of silicon oxide, silicon nitride, silicon oxy-nitride, or combinations thereof.

7. The dual CESL process according to claim 1 wherein the second-stress imparting film is a compressive contact etch stop layer (C-CESL).

8. The dual CESL process according to claim 7 wherein the second-stress imparting film is made of silicon oxide, silicon nitride, silicon oxy-nitride, or combinations thereof.

9. The dual CESL process according to claim 1 wherein the first stress is tensile stress.

10. The dual CESL process according to claim 1 wherein the transversal direction is channel width direction.

11. A dual contact etch stop layer (dual CESL) process, comprising:
providing a substrate having thereon a first device region, a second device region and a shallow trench isolation (STI) region between the first and second device regions, wherein a gate structure overlies the first device region, the second device region and the STI region, and wherein the gate structure comprises a contact region on the STI region, which is approximately at a middle point between the first and second device regions;
forming a first-stress imparting film with a first stress over the substrate, wherein the first-stress imparting film does not cover the second device region; and
forming a second-stress imparting film with a second stress over the substrate, wherein the second-stress imparting film does not cover the first device region, an overlapped boundary between the first- and second-stress imparting films is created directly above the STI region, and wherein the overlapped boundary is placed in close proximity to the second device region and does not overlap with the contact region.

12. The dual CESL process according to claim 11 wherein a well boundary is situated underneath the STI region, and wherein the overlapped boundary is not aligned with the well boundary.

13. The dual CESL process according to claim 11 wherein a spacing s between the overlapped boundary and the STI-second device region boundary is less than or equal to one fourth of a spacing w between the first and second device regions (s≦¼ w).

14. The dual CESL process according to claim 11 wherein the first device region is an NMOS device region and the second device region is a PMOS device region.

15. The dual CESL process according to claim 11 wherein the first-stress imparting film is a tensile contact etch stop layer (T-CESL).

16. The dual CESL process according to claim 15 wherein the first-stress imparting film is made of silicon oxide, silicon nitride, silicon oxy-nitride, or combinations thereof.

17. The dual CESL process according to claim 11 wherein the second-stress imparting film is a compressive contact etch stop layer (C-CESL).

18. The dual CESL process according to claim 17 wherein the second-stress imparting film is made of silicon oxide, silicon nitride, silicon oxy-nitride, or combinations thereof.

19. The dual CESL process according to claim 11 wherein the first stress is tensile stress.
